(19) United States
(12) Patent Application Publication
(10) Pub. No.: US 2024/0418791 A1
(43) Pub. Date: Dec. 19, 2024

(54) Aerosol Generation Device Battery Verification

(71) Applicant: JT International SA, Geneva (CH)

(72) Inventor: Grzegorz Aleksander Pilatowicz, Grens (CH)

(73) Assignee: JT International SA, Geneva (CH)

(21) Appl. No.: 18/698,588

(22) PCT Filed: Oct. 6, 2022
(86) PCT No.: PCT/EP2022/077827

§ 371 Date: Apr. 4, 2024

(30) Foreign Application Priority Data
Oct. 8, 2021 (EP) 21201655.4

(51) Int. Cl. G01R 31/392; A24F 40/80; G01R 31/389

(52) U.S. Cl. CPC G01R 31/392; A24F 40/80; G01R 31/389

(57) ABSTRACT

There is provided an aerosol generation device battery verification system. The system comprises a battery measurement module (152), a battery verification module (154), and a controller (104). The battery measurement module is configured to perform a plurality of battery voltage measurements of a battery (104) connected to an aerosol generation device (100). The battery verification module is configured to determine whether a parameter of the battery meets a verification requirement based upon the plurality of battery voltage measurements. The controller is configured to set the aerosol generation device to an operable state when the parameter meets the verification requirement, and further configured to set the aerosol generation device to a restricted state when the parameter does not meet the verification requirement.

### FIELD OF INVENTION

The present invention relates to aerosol generation devices, and more particularly battery verification in aerosol generation devices.

### BACKGROUND

Aerosol generation devices such as electronic cigarettes and other aerosol inhalers or vaporisation devices are becoming increasingly popular consumer products.

Heating devices for vaporisation or aerosolisation are known in the art. Such devices typically include a heating chamber and heater. In operation, an operator inserts the product to be aerosolised or vaporised into the heating chamber. The product is then heated with an electronic heater to vaporise the constituents of the product for the operator to inhale. In some examples, the product is a tobacco product similar to a traditional cigarette. Such devices are sometimes referred to as “heat not burn” devices in that the product is heated to the point of aerosolisation, without being combusted.

Aerosol generation devices are typically powered by a power system that includes a battery. Replacing such a battery presents problems in ensuring battery safety, reliability and quality in the new battery, as well as ensuring that a correct or approved battery is used, and that the new battery is not in fact an aged, damaged or inappropriate battery for the aerosol generation device.

### SUMMARY OF INVENTION

An object of the present invention is to address the aforementioned problems, amongst others.

In a first aspect, there is provided an aerosol generation device battery verification system, the system comprising:
a battery measurement module configured to perform a plurality of battery voltage measurements of a battery connected to an aerosol generation device;
a battery verification module configured to determine whether a parameter of the battery meets a verification requirement based upon the plurality of battery voltage measurements; and
a controller configured to set the aerosol generation device to an operable state when the parameter meets the verification requirement, and further configured to set the aerosol generation device to a restricted state when the parameter does not meet the verification requirement.

Characteristics of the battery, based upon the plurality of voltage measurements can be indicative of whether or not the battery is an approved battery. By performing a plurality of battery voltage measurements of the battery, it can be determined whether a parameter of the battery meets a verification requirement based upon these measurements. In this way, the aerosol generation device can be controlled to be in an operable state when the parameter meets the verification requirement, and in a restricted state when the parameter does not meet the verification requirement. As such, for a non-approved battery, or an aged, damaged or inappropriate battery, the use of the aerosol generation device is restricted. This provides a robust, accurate and cost-effective method for determining if a battery fulfils requirements for use in the aerosol generation device, and can be authorized for a safe and reliable use of the device, thereby improving battery safety, as well as reliability and quality of the operation of the aerosol generation device.

Preferably, the aerosol generation device battery verification system is configured to apply a first battery pulse and a second battery pulse at a predetermined time interval after the first battery pulse, and the battery measurement module is configured to measure the plurality of battery voltage measurements based upon the first battery pulse and the second battery pulse.

In this way, battery measurements can be determined for, and averaged across, multiple loads having been applied to the battery, thereby improving the determination of whether the parameter of the battery meets the verification requirement.

Preferably, the aerosol generation device battery verification system is configured to apply the first battery pulse and the second battery pulse as discharging battery pulses in which power flows from the battery to a heater of the aerosol generation device; and/or
wherein the aerosol generation device battery verification system is configured to apply the first battery pulse and the second battery pulse as charging battery pulses in which power flows to the battery from a second power source.

In this way, the flexibility of the verification process is improved.

Preferably, the aerosol generation device battery verification system is configured to apply the first battery pulse and the second battery pulse as discharging battery pulses when a state of charge of the battery is greater than a predetermined state of charge threshold.

In this way, when the battery has a sufficient state of charge, the verification process can be performed using a discharging pulse; a discharging pulse is beneficial as the available discharging power is higher than charging power. Using the discharging power allows for a more accurate internal resistance calculation as the voltage drop will be higher, meaning that the impact of voltage measurement inaccuracies on the internal resistance calculation is lower. The discharging pulse also contributes to a bigger quasi-open circuit voltage drop which is also beneficial. for the same reasons, as a higher current will discharge the battery more in the same time than a lower current, allowing for a higher change in voltage.

Preferably, the aerosol generation device battery verification system is configured to apply the first battery pulse and the second battery pulse as charging battery pulses when a state of charge of the battery is not greater than a predetermined state of charge threshold.

In this way, when the battery does not have a sufficient state of charge, the verification process can be performed with a charging pulse. When a battery has a low state of charge, discharging battery characteristics can become less repeatable; using a charging pulse avoids these effects and therefore improves the accuracy of the verification process.

Preferably, the second power source comprises one or more supercapacitors in the aerosol generation device; or
the second power source comprises an external power source to which the aerosol generation device is connected.

Preferably, determining whether the parameter of the battery meets the verification requirement comprises at least one of:
calculating an internal resistance of the battery based upon the plurality of battery voltage measurements, and determining that the parameter of the battery meets the verification requirement when the calculated internal resistance is within a predetermined internal resistance range;
calculating a change in voltage of the battery based upon the plurality of battery voltage measurements, and determining that the parameter of the battery meets the verification requirement when the change in voltage of the battery falls within a predetermined voltage change range;
calculating an available capacity of the battery based upon the plurality of battery voltage measurements, and determining that the parameter of the battery meets the verification requirement when the calculated available capacity of the battery is within a predetermined capacity range; and/or
calculating an available capacity of the battery and an internal resistance of the battery based upon the plurality of battery voltage measurements, and determining that the parameter of the battery meets the verification requirement when the calculated available capacity of the battery is within a predetermined capacity range for the calculated internal resistance of the battery.

In this way, the determination of whether of whether the battery is a verified battery can be accurately determined based upon one or more parameters.

Preferably, the plurality of battery voltage measurements comprise battery voltage measurements measured before the first battery pulse, during the first battery pulse, between the first battery pulse and the second battery pulse, during the second battery pulse, and after the second battery pulse; and
the battery verification module is configured to calculate the internal resistance of the battery based upon the battery voltage measurements before the first battery pulse, during the first battery pulse, between the first battery pulse and the second battery pulse, and during the second battery pulse.

In this way, the battery measurements are taken at different points in the two battery pulses, when the battery is under different conditions, thereby allowing for an accurate determination of whether the parameter meets the verification requirement.

Preferably, the plurality of battery voltage measurements comprise a first open circuit battery voltage measured between the first battery pulse and the second battery pulse, and a second open circuit battery voltage measured after the second battery pulse; and
the battery verification module is configured to calculate the available capacity of the battery based upon the first open circuit battery voltage, and the second open circuit battery voltage.

Preferably, determining whether the parameter of the battery meets the verification requirement comprises calculating an internal resistance of the battery based upon the plurality of battery voltage measurements, and determining that the parameter of the battery meets the verification requirement when the calculated internal resistance is within a predetermined internal resistance range. Preferably, the plurality of battery voltage measurements comprise battery voltage measurements measured before the first battery pulse, during the first battery pulse, between the first battery pulse and the second battery pulse, and during the second battery pulse, and the battery verification module is configured to calculate the internal resistance of the battery based upon the battery voltage measurements before the first battery pulse, during the first battery pulse, between the first battery pulse and the second battery pulse, and during the second battery pulse. Preferably, the predetermined internal resistance range is based upon a state of charge of the battery. Preferably, the predetermined internal resistance range is based upon a state of charge of the battery and an ambient temperature proximal to the aerosol generation device.

Preferably, determining whether the parameter of the battery meets the verification requirement comprises calculating a change in voltage of the battery based upon the plurality of battery voltage measurements, and determining that the parameter of the battery meets the verification requirement when the change in voltage of the battery falls within a predetermined voltage change range. Preferably, the plurality of battery voltage measurements comprise a first open circuit battery voltage measured between the first battery pulse and a second open circuit battery voltage measured after the second battery pulse, and the change in voltage of the battery is determined as a difference between the first open circuit battery voltage and the second open circuit battery voltage.

Preferably, determining whether the parameter of the battery meets the verification requirement comprises calculating an available capacity of the battery based upon the plurality of battery voltage measurements, and determining that the parameter of the battery meets the verification requirement when the calculated available capacity of the battery is within a predetermined capacity range. Preferably, the plurality of battery voltage measurements comprise a first open circuit battery voltage measured between the first battery pulse and the second battery pulse, and a second open circuit battery voltage measured after the second battery pulse, and the battery verification module is configured to calculate the available capacity of the battery based upon the first open circuit battery voltage, the second open circuit battery voltage, and an integrated current during the second battery pulse.

Preferably, determining whether the parameter of the battery meets the verification requirement comprises calculating an available capacity of the battery and an internal resistance of the battery based upon the plurality of battery voltage measurements, and determining that the parameter of the battery meets the verification requirement when the calculated available capacity of the battery is within a predetermined capacity range for the calculated internal resistance of the battery. Preferably, the battery verification module is configured to: calculate the available capacity of the battery based upon a first open circuit battery voltage measured between the first battery pulse and the second battery pulse, a second open circuit battery voltage measured after the second battery pulse, and an integrated current during the second battery pulse, and calculate the internal resistance of the battery based upon battery voltage measurements before the first battery pulse, during the first battery pulse, between the first battery pulse and the second battery pulse, and during the second battery pulse, wherein the predetermined capacity range based upon a relationship between internal resistance and capacity range of the battery.

Preferably, the operable state comprises an unlocked state in which an aerosolisation session can be performed, and the restricted state comprises a locked state in which an aerosolisation session cannot be performed.

Preferably, the aerosol generation device battery verification system further comprises a temperature sensor module configured to determine an ambient temperature proximal to the aerosol generation device, and the battery measurement module is configured to perform the plurality of battery voltage measurements when the determined ambient temperature is greater than a predetermined temperature threshold, and configured to not perform the plurality of battery voltage measurements when the determined ambient temperature is not greater than a predetermined temperature threshold.

Low temperatures (i.e. below the predetermined temperature threshold) in the environment in which the device is located (i.e. the environmental temperature external to the device) can adversely affect the battery chemistry, thereby reducing the reliability of the battery verification process. Inhibiting the verification process at such low temperatures avoids this, thereby improving the reliability of the verification process.

Preferably, the system is configured to be communicatively coupled to an external device;
the external device is configured to receive an input indicating a type of battery connected to the aerosol generation device, and determine the verification requirement for the battery; and
the aerosol generation device battery verification system is configured to receive the verification requirement from the external device.

In this way, the verification requirements can be provided by the external device, rather than the verification system of the aerosol generation device having them pre-stored. In this way, a better use of the computational resources of the aerosol generation device battery verification system is made in reducing the memory and storage resources required for the battery verification system.

Preferably, the battery measurement module is configured to perform a plurality of battery voltage measurements in response to a battery being connected to the aerosol generation device. Preferably, the battery being connected to the aerosol generation device is a newly connected battery.

In a second aspect, there is provided an aerosol generation device comprising the aerosol generation device battery verification system of the first aspect.

In a third aspect, there is provided aerosol generation device battery verification method, the method comprising:
performing a plurality of battery voltage measurements of a battery connected to an aerosol generation device;
determining whether a parameter of the battery meets a verification requirement based upon the plurality of battery voltage measurements; and
setting the aerosol generation device to a operable state when the parameter meets the verification requirement, and setting the aerosol generation device to a restricted state when the parameter does not meet the verification requirement.

Preferably, the method comprises the preferable features of the first aspect, as appropriate.

In a further aspect, there is provided a non-transitory computer-readable medium storing instructions that when executed by one or more processors of an aerosol generation device battery verification system cause the one or more processors to perform steps comprising:
performing a plurality of battery voltage measurements of a battery connected to an aerosol generation device;
determining whether a parameter of the battery meets a verification requirement based upon the plurality of battery voltage measurements; and
setting the aerosol generation device to a operable state when the parameter meets the verification requirement, and setting the aerosol generation device to a restricted state when the parameter does not meet the verification requirement.

Preferably, the non-transitory computer-readable medium storing instructions comprises the preferable features of the first aspect, as appropriate.

### BRIEF DESCRIPTION OF THE DRAWINGS

Embodiments of the invention are now described, by way of example, with reference to the drawings, in which:

FIG. 1 is a block diagram of an aerosol generation device;

FIG. 2A is a plot of power delivered to the heater of an aerosol generation device, against time, for an aerosolisation session;

FIG. 2B is an exemplary circuit diagram of power system electronics of an aerosol generation device;

FIG. 3 is a flow diagram of a process of connecting a new battery to the aerosol generation device;

FIG. 4 is a flow diagram of the process of battery verification performed by a battery measurement module and a battery verification system; and

FIG. 5 is a flow diagram of the process of battery verification performed by a battery verification module and a battery verification system.

### DETAILED DESCRIPTION

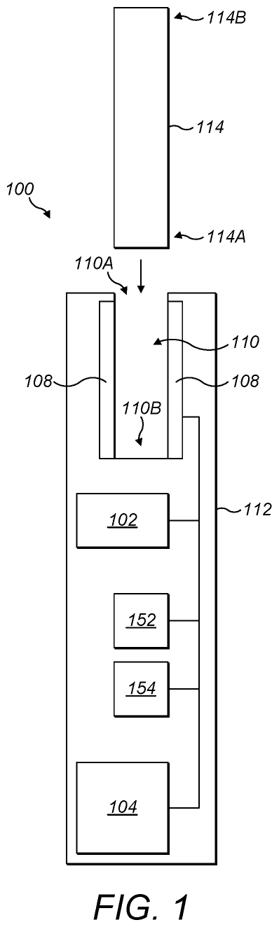

FIG. 1 shows a block diagram of the components of an aerosol generation device 100 or a vapor generation device, also known as an electronic cigarette. For the purposes of the present description, it will be understood that the terms vapor and aerosol are interchangeable.

The aerosol generation device 100 has a body portion 112 containing a controller 102, and a power system comprising a battery 104. Whilst described as a single battery herein, the battery 104 can be one or more batteries or battery pack(s). In some example, the power system can also comprise one or more supercapacitors as a component of a ‘dual power system’ that comprises both a battery and a supercapacitor.

The controller 102 is arranged to control the operation of the aerosol generation device. This can include inhibiting and enabling the operation of the device, as well as controlling a power flow of the battery 104 based upon the operating mode of the aerosol generation device. The controller 102 can be at least one microcontroller unit comprising memory, with instructions stored thereon for operating the aerosol generation device 100 including instructions for inhibiting and enabling the operation of the device, instructions for executing operating modes of the device, instructions for controlling the power flow from the battery, and the like, and one or processors configured to execute the instructions.

In an example, a heater 108 is contained with the body portion 112. In such an example, as shown in FIG. 1, the heater 108 is arranged in a cavity 110 or chamber in the body portion 112. The cavity 110 is accessed by an opening 110A in the body portion 112. The cavity 110 is arranged to receive an associated aerosol generating consumable 114. The aerosol generating consumable can contain an aerosol generating material, such as a tobacco rod containing tobacco. A tobacco rod can be similar to a traditional cigarette. The cavity 110 has cross-section approximately equal to that of the aerosol generating consumable 114, and a depth such that when the associated aerosol generating consumable 114 is inserted into the cavity 110, a first end portion 114A of the aerosol generating consumable 114 reaches a bottom portion 110B of the cavity 110 (that is, an end portion 110B of the cavity 110 distal from the cavity opening 110A), and a second end portion 114B of the aerosol generating consumable 114 distal to the first end portion 114A extends outwardly from the cavity 110. In this way, a consumer can inhale upon the aerosol generating consumable 114 when it is inserted into the aerosol generation device 100. In the example of FIG. 1, the heater 108 is arranged in the cavity 110 such that the aerosol generating consumable 114 engages the heater 108 when inserted into the cavity 110. In the example of FIG. 1, the heater 108 is arranged as a tube in the cavity such that when the first end portion 114A of the aerosol generating consumable is inserted into the cavity the heater 108 substantially or completely surrounds the portion of the aerosol generating consumable 114 within the cavity 110. The heater 108 can be a wire, such as a coiled wire heater, or a ceramic heater, or any other suitable type of heater. The heater 108 can comprise multiple heating elements sequentially arranged along the axial length of the cavity that can be independently activated (i.e. powered up) in a sequential order.

In an alternative embodiment (not shown), the heater can be arranged as an elongate piercing member (such as in the form of needle, rod or blade) within the cavity; in such an embodiment the heater can be arranged to penetrate the aerosol generating consumable and engage the aerosol generating material when the aerosol generating consumable is inserted into the cavity.

In another alternative embodiment (not shown), the heater may be in the form of an induction heater. In such an embodiment, a heating element (i.e., a susceptor) can be provided in the consumable, and the heating element is inductively coupled to the induction element (i.e., induction coil) in the cavity when the consumable is inserted into the cavity. The induction heater then heats the heating element by induction.

It will be understood from the foregoing that the heater 108 can be a heater component such as a heating element or induction coil. Hereinafter, such a heater component is referred to the as a heater, although it will be understood that this term can refer to any of the aforementioned heater components as well as a heater more generally.

The heater 108 is arranged to heat the aerosol generating consumable 114 to a predetermined temperature to produce an aerosol in an aerosolisation session. An aerosolisation session can be considered as when the device is operated to produce an aerosol from the aerosol generating consumable 114. In an example in which the aerosol generating consumable 114 is a tobacco rod, the aerosol generating consumable 114 comprises tobacco. The heater 108 is arranged to heat the tobacco, without burning the tobacco, to generate an aerosol. That is, the heater 108 heats the tobacco at a predetermined temperature below the combustion point of the tobacco such that a tobacco-based aerosol is generated. The skilled person will readily understand that the aerosol generating consumable 114 does not necessarily need to comprise tobacco, and that any other suitable substance for aerosolisation (or vaporisation), particularly by heating without burning the substance, can be used in place of tobacco.

In an alternative, the aerosol generating consumable can be a vaporisable liquid. The vaporisable liquid can be contained in a cartridge receivable in the aerosol generation device, or can be directly deposited into the aerosol generation device.

The aerosol generation device further comprises a battery verification system. The battery verification system includes a battery measurement module 152 and a battery verification module 154. The controller 102 can also be a component of the battery verification system. As will be described in more detail subsequently, the battery measurement module 152 is configured to perform a plurality of battery voltage measurements of the battery 104 connected to the aerosol generation device 100. The battery verification module 154 is configured to determine whether a parameter of the battery 104 meets a verification requirement based upon the plurality of battery voltage measurements. The controller 102 is configured to set the aerosol generation device to an operable state when the parameter meets the verification requirement, and further configured to set the aerosol generation device to a restricted state when the parameter does not meet the verification requirement. In some examples, the battery measurement module 152 and the battery verification module 154 may be modules comprised within the controller 102. In other examples, the battery measurement module 152 and the battery verification module 154 may be separate from but in communication with the controller 102.

It will also be understood that the steps performed by the battery measurement module 152 and battery verification module 154 can be performed by the controller 102 as a single module (e.g. a single microcontroller), or by multiple different modules. That is, a dedicated controller 102, a separate dedicated battery measurement module 152, and a separate dedicated battery verification module 154 are not required; rather, the described aerosol generation device battery verification system can be implemented using one or more suitable processing modules with suitable hardware for performing the steps (described subsequently) for the aerosol generation device battery verification process. The controller configured to set the aerosol generation device to an operable state when the parameter meets the verification requirement, and further configured to set the aerosol generation device to a restricted state when the parameter does not meet the verification requirement, need not be the main controller that controls the complete operation of the aerosol generation device, but could rather be separate controller (in communication with the main controller) that is used for the battery verification process.

The controller 102 is arranged to control the power flow of the battery 104 in the aerosolisation session. The aerosolisation session can include a preheating phase and a heating phase.

In the preheating phase, the heater 108 associated with the aerosol generation device 100 is heated to a predetermined temperature for the generation of an aerosol from the aerosol generating consumable 114. The preheating phase can be considered the time during which a preheating mode is being executed, for example the time it takes for the heater 108 to reach the predetermined temperature. The preheating mode occurs during a first time period of the aerosolisation session. In an example, the first time period can be a fixed predetermined time period. In other examples, the first time period can vary corresponding to the length of time needed to heat the heater 108 to the predetermined temperature.

When the preheating phase is complete, the controller 102 ends the preheating mode 202 and controls the power system to perform the heating phase 204. In the heating phase the controller 102 controls the power flow from the power system to maintain the heater 108 substantially at the predetermined temperature so that an aerosol is generated for the consumer to inhale. A heating phase can be considered the time during which a heating mode is being executed, for example the time during which the heater 108 is aerosolising one (or at least part of one) aerosol generating consumable 114 after the preheating phase. The controller 102 can control the power system to operate the heating mode for a second time period of the aerosolisation session. The second time period can be predetermined and stored at the controller 102.

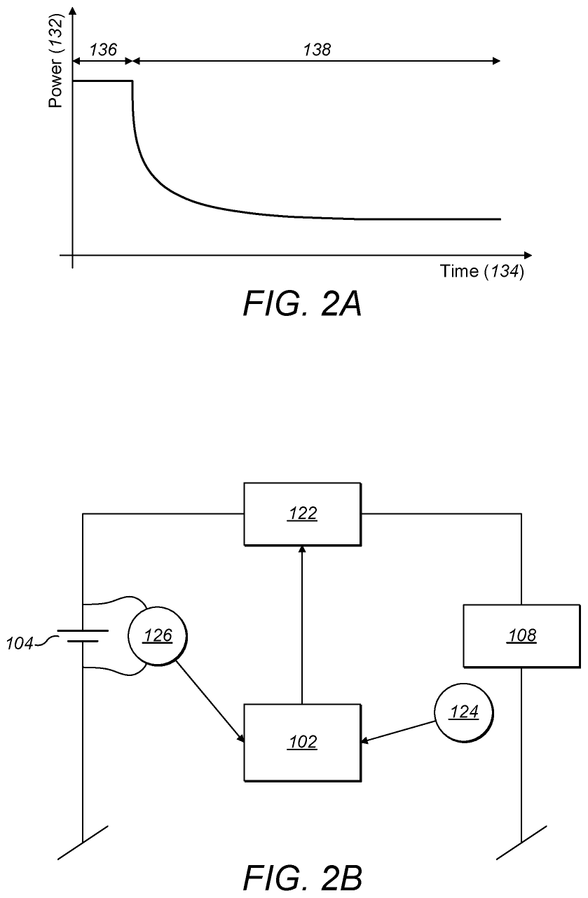

FIG. 2A shows an exemplary plot of average power 132 delivered to the heater 108 against time 134 for an aerosolisation session. In the pre-heating phase the controller 102 controls the power system to apply power to the heater 108 for the first time period 136, until the heater temperature reaches the predetermined temperature. In an example, the predetermined temperature may be 230° C. In an example, the first time period is 20 seconds. In some examples, the controller 102 is configured to heat the heater 108 to the predetermined temperature within a fixed predetermined first time period. In other examples the first time period varies depending on how long the heater 108 takes to reach the predetermined temperature.

When the heater 108 reaches the predetermined temperature, the controller 102 switches the operating mode to the heating phase for the second time period 138 and maintains the heater temperature substantially at the predetermined temperature for this second time period 138. In an example, the second time period may be 250 seconds. Typically, a lower power level is applied to the heater 108 in the heating phase when maintaining the heater 108 at the predetermined temperature, than the power level applied to the heater 108 to heat it to the predetermined temperature in the preheating phase. This can be seen in FIG. 2A in that the power delivered to the heater 108 in the second time period 138 is lower than the power delivered to the heater 108 in the first time period 136. The power level delivered to the heater 108 can be controlled by various means, for example adjusting the power output from the battery 104, or by adjusting the on/off periods in a pulse width modulated power flow (as subsequently described).

Following the aerosolisation session the user of the aerosol generation device may be informed that the aerosolisation session has ended, by way of a visual, haptic or audible indicator for example, so that they are aware that the consumable is no longer being aerosolised.

FIG. 2B shows an exemplary circuit diagram of power system electronics of the aerosol generation device 100. The power system electronics comprise the battery 104, the controller 102, and the heater 108. The power system electronics can further comprise a pulse width modulation (PWM) module 122 that is controlled by the controller 102. The PWM module 122 is configured to apply a pulse width modulation to the power flow from the battery 104 to the heater 108 for an aerosolisation session. The controller 102 can control the duty cycle of the pulse width modulation in order to control the power applied to heater 108. For example, when preheating, a high duty cycle can be applied to rapidly heat the heater 108.

When the heater 108 is being maintained at the aerosolisation temperature, in the heating mode, a lower duty cycle can be applied. The PWM module 122 can comprise a switch, such as a transistor, controlled by the controller 102 to switch between the “on state” and “off state” of each PWM period. A heater temperature sensor or heater temperature sensing circuit 124 can be arranged at the heater 108 or in the chamber 110 to monitor the heater temperature. The heater temperature is fed back to the controller 102. When the controller 102 determines that the heater temperature has moved above the aerosolisation temperature, the power level applied to the heater 108 can be decreased (for example by reducing the PWM duty cycle). Likewise, when the controller 102 determines that the heater temperature has dropped below the aerosolisation temperature, the power level applied to the heater 108 can be increased (for example by increasing the PWM duty cycle).

A voltage sensor or voltage sensing circuit 126 can be connected to the battery 104, to act as a voltmeter and feedback the battery voltage to the controller 102, so that the controller 102 can monitor the charge status of the battery 104, and other battery parameters, by determining the voltage level of the battery 104.

In FIG. 2B, the respective connections between the controller 102 and the voltage sensor 126, PWM module 122, and heater temperature sensor 124 are represented by arrows for simplicity. However, the skilled person will understand that typical electrical connections between a controller and these components can be used.

The aerosol generation device 100 can further comprise an ambient temperature sensor (not shown) configured to measure the ambient temperature of the air proximal to the aerosol generation device, and feedback the ambient temperature to the controller 102.

In an example, the battery 104 is a rechargeable or secondary battery, such as a lithium-ion battery. To improve sustainability, an aged battery of an aerosol generation device can be replaced, rather than replacing the entire aerosol generation device. When a new battery 104 is connected to the aerosol generation device 100 a battery verification process is performed. Determining that a verified battery has been connected to the aerosol generation device is advantageous in ensuring battery safety, reliability and quality.

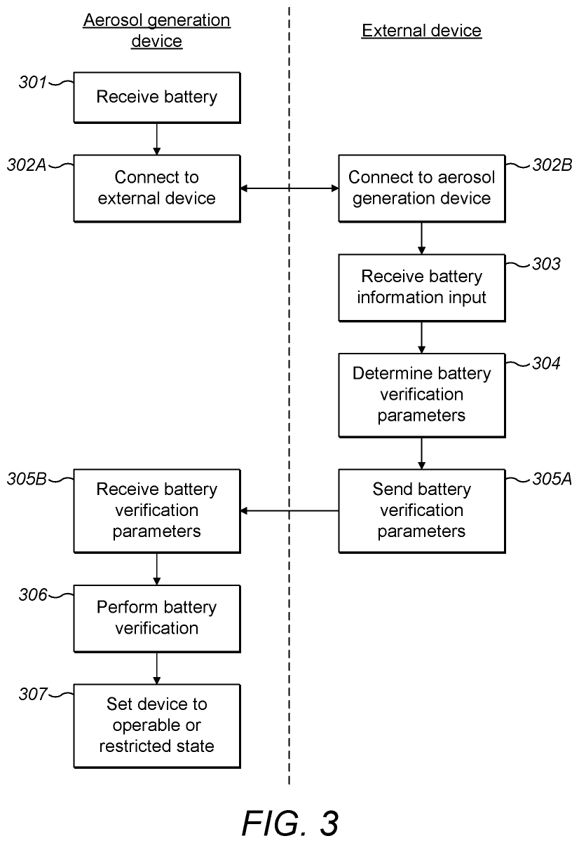

FIG. 3 shows an overview of a process of connecting a new battery to the aerosol generation device.

At step 301, a battery 104 is received in the aerosol generation device. For example, this can be brought about by a user of the device, or a technician, inserting a new battery 104. In some example, the new battery 104 may be inserted to replace an older battery that has reached the end of the its useful working life, or the new battery 104 may be inserted into a new aerosol generation device before it is first operated by the user.

At step 302, the aerosol generation device is connected to an external device.

In an example, the external device can be a smartphone, computer, tablet computer, or the like. The connection between the aerosol generation device and the external device can be a wireless connection, for example using Bluetooth, Near-Field Communication, Wi-Fi, or the like. Alternatively, the connection between the aerosol generation device and the external device can be a wired connection, for example using a USB connection or the like.

At step 302A the aerosol generation device initiates the connection to the external device, and at step 302B the external device responds to establish the connection. Alternatively, at step 302B, the external device can initiate the connection to the aerosol generation device, and at step 302A the aerosol generation device responds to establish the connection.

At step 303, an application associated with the aerosol generation device is loaded on the external device. A user interface is presented in which the operator of the device is prompted to enter battery information, such as the type of battery 104 inserted into the aerosol generation device. Such information may include a model number and/or manufacturer details of the battery 104.

Alternatively, or additionally, at step 303, the operator can be presented with an interface that utilises a camera of the external device to receive an input of the battery information by scanning a machine readable label (such as a barcode or QR code) associated with the battery 104. For example, this may be on the battery 104 itself, or on/included in packaging associated with the battery 104. That is, the machine readable label can be used by the application to determine the type of battery 104. The user may then be asked, by the application, to confirm that determined battery 104 is correct.

In some examples, step 303 can occur before the new battery 104 is received in the aerosol generation device at step 301.

At step 304, the application looks up battery verification parameters, based upon the received battery information, for the type of battery 104 that has been connected to the aerosol generation device. For example, this can be by a look-up in a locally stored database, or a remotely stored database that is accessible by the application.

At step 305A, the application sends the battery verification parameters to the aerosol generation device using the established communication channel between the two. At the step 305B, the aerosol generation device receives the battery verification parameters. The battery verification parameters can then be stored in storage accessible by the controller 102.

In an alternative, the battery verification parameters can be pre-stored in the storage accessible by the controller 102 so that the connection to the external device is not required.

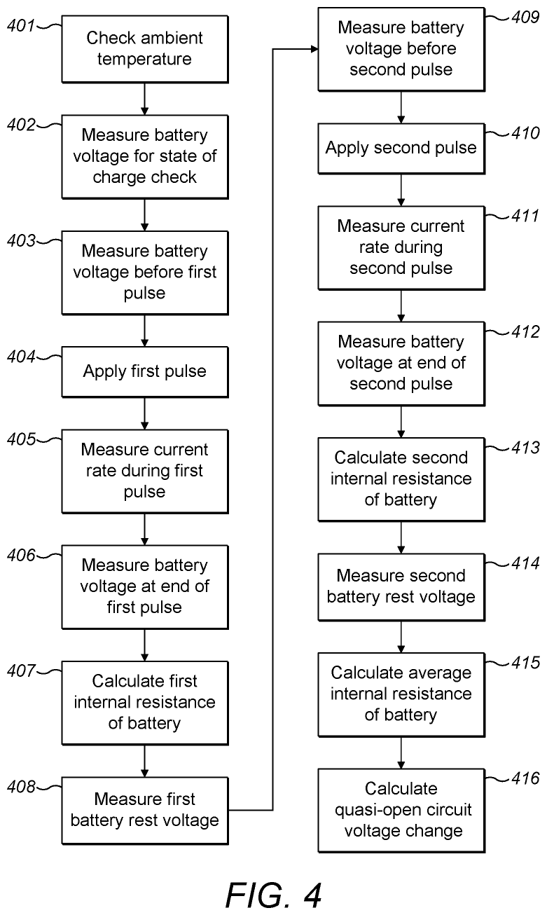

At step 306, the controller 102 performs the battery verification process using the battery measurement module 152 and battery verification module 154, as described in more detail with reference to FIG. 4.

At step 307, when the received battery 104 is determined to meet a battery verification requirement in the battery verification process, the controller 102 sets the aerosol generation device to an operable state. When the received battery 104 is determined to not meet a battery verification requirement in the battery verification process, the controller 102 sets the aerosol generation device to a restricted state. The operable state comprises an unlocked state in which an aerosolisation session can be performed by the aerosol generation device, and the restricted state comprises a locked state in which an aerosolisation session cannot be performed by the aerosol generation device.

In this way, if the battery 104 received in the aerosol generation device is successfully verified, it can be used with the aerosol generation device for an aerosolisation session. However, if the battery 104 received in the aerosol generation is not verified, it cannot be used with the aerosol generation device for an aerosolisation session. This ensures battery safety, reliability, and quality as only verified batteries can be used for an aerosolisation session.

FIG. 4 presents the battery verification process of step 307 of FIG. 3 in more detail.

At step 401, the battery verification system can determine an ambient temperature proximal to the aerosol generation device using the ambient temperature sensor. When the determined ambient temperature is greater than or equal to a predetermined temperature threshold, the process continues to step 402 and the battery measurement module 152 performs a plurality of battery voltage measurements. When the determined ambient temperature is not greater than or equal to the predetermined temperature threshold the verification process is not performed, and a notification can be presented to the operator of the device to move the device to a warmer environment. This notification can be indicated to the operator by way of an indicator in the aerosol generation device, for example a visual indicator (such as a light source, or display screen), an audible indicator (such as a speaker emitting a noise), or a haptic indicator (for example, vibrating in a predetermined manner). In an example, the predetermined temperature threshold can be 15° C. This is advantageous as low temperatures (i.e. below the predetermined temperature threshold) can adversely affect the battery chemistry, thereby reducing the reliability of the battery verification process.

At step 402, the battery verification system can determine the state of charge of the battery 104 by measuring the battery voltage at rest as part of a rough state of charge check. In an example, this can be achieved by the battery measurement module 152 controlling the battery 104 to apply a small, or negligible, ‘trickle’ current to the electronics of the device (e.g. by a start-up of a Bluetooth module) for a short time period (e.g. 1 second), with the battery voltage is then measured with the voltage sensor using this small current. The determined battery voltage is converted to a state of charge (SoC) figure for the battery 104, such as a SoC percentage. The conversion to a SoC percentage can be carried out using a look-up table of battery voltages and respective SoC percentages for the specific type of battery 104. This look-up table can be included in the battery verification parameters described at step 305.

The battery verification process utilises a plurality of voltage pulses, and the battery voltage measurements, as well as other parameters are determined based upon these pulses. These battery pulses can be discharging pulses in which power flows from the battery 104, or charging pulses in which power flows to the battery 104. When the determined SoC at step 402 is greater than or equal to a (first) SoC threshold (e.g. 20%) the battery verification process is performed using discharging battery pulses from the battery 104 to the heater 108. At low SoCs, battery discharging behaviour can be become less repeatable. As such, if the determined SoC is less than the SoC threshold, the battery verification process is performed using charging battery pulses in which power is provided to the battery 104.

In some examples, a second SoC threshold can also be implemented. The second SoC threshold can be lower than the first SoC threshold. Below this lower second SoC threshold (e.g. 10%, or in some cases 5%) the battery behaviour can become non-linear and is less repeatable. As such, when the determined SoC is less than the second SoC threshold, the controller 102 can control the device to indicate, using an indicator integrated into the device, to the operator that the battery 104 needs to be charged before the verification process can take place so as to increase the SoC.

In some examples, the system may be configured to use only discharging pulses, or only charging pulses. For example, only charging pulses can be used in aerosol generation devices for which a discharging pulse would not suitable, such as when there is no integral heating element.

Charging pulses to the battery 104 can be applied in two exemplary ways. In a first example, the operator of the device can be prompted by an interface of the device to connect the device to an external power supply. When the external power supply is connected, the battery measurement module 152 controls the power flow from the external power supply to the battery 104 such that charging battery pulses are applied from the external power supply to the battery 104. In a second example, in which the power system is a dual power system comprising the battery 104 and a supercapacitor, the battery measurement module 152 controls a power flow from the supercapacitor to the battery 104 such that charging battery pulses are applied from the supercapacitor to the battery 104.

In the following description, the described battery pulses are discharging battery pulses from the battery 104 to the heater 108. However, the skilled person will readily understand that these can be substituted for charging battery pulses (e.g. from an external power source, or supercapacitor in a dual power system) as previously described.

At step 403, the battery measurement module 152 measures the voltage (V_{before_first_pulse}) of the battery 104, using the voltage sensor, shortly before the first battery pulse. In an example, the measurement of V_{before_first_pulse} takes 100 ms or less, and can take place 100 ms (or less) before the first pulse is applied, such that it is completed before the first pulse is applied. This voltage can be measured by applying a small, or negligible, ‘trickle’ current from the battery 104 to the electronics.

In some examples, the battery voltage measurement at step 402 can also be used as the value of V_{before_first_pulse}; however, using a separate measurement of the voltage at step 403 can avoid issues relating to long time constants in the battery affecting the measured voltage.

At step 404, the battery measurement module 152 controls the battery 104 to apply a first pulse to the heater 108. This first pulse can be applied at a predetermined power level for a predetermined time period. In an example, the predetermined power level is 30 W and the predetermined time period is 10 seconds. Preferably, the predetermined time period should be long enough to encompass information about both the ohmic internal resistance of the battery 104 as well as electrochemical and diffusion related resistances.

At step 405, the battery measurement module 152 measures the current rate that is applied from the battery 104 during the first pulse (I_{first_pulse}). The current rate can be considered the average current applied during the first pulse.

At step 406, the battery measurement module 152 controls the voltage sensor to measure the battery voltage near to the end of the first pulse (V_{end_first_pulse}), but whilst the first pulse is still being applied. In an example, the measurement of V_{end_first_pulse} takes place less than 100 ms before the end of the first pulse.

The battery measurement module 152 can also control the ambient temperature sensor to measure the temperature during the first pulse.

At step 407, the battery measurement module 152 calculates a first internal resistance (R_{I_1}) of the battery 104; that is, the internal resistance of the battery 104 based upon the first pulse.

The first internal resistance can be calculated as:

$${R}_{I \_ 1} = \frac{{V}_{before\_first \_pulse} - {V}_{end\_first \_pulse}}{{I}_{first\_pulse}}$$

At step 408, the battery measurement module 152 controls the voltage sensor to measure the battery voltage at rest, or open circuit voltage, after the first pulse has been applied (V_{OCV_1}). In an example, V_{OCV_1} is measured 1 second after the first pulse ends. This voltage can be measured by applying a small, or negligible, ‘trickle’ current from the battery 104 to the electronics.

At step 409, the battery measurement module 152 measures the voltage (V_{before_second_pulse}) of the battery 104, using the voltage sensor, shortly before the second battery pulse. In an example, the measurement of V_{before_second_pulse} takes 100 ms or less, and can take place 100 ms (or less) before the second pulse is applied, such that it is completed before the second pulse is applied. This voltage can be measured by applying a small, or negligible, ‘trickle’ current from the battery 104 to the electronics. In some examples, the value of V_{OCV_1} can be used as the value of V_{before_second_pulse}.

At step 410, the battery measurement module 152 controls the battery 104 to apply a second pulse to the heater 108. This second pulse can be applied at the predetermined power level for the predetermined time period, as with the first pulse.

At step 411, the battery measurement module 152 measures the current rate that is applied from the battery 104 during the first pulse (I_{second_pulse}). The battery measurement module 152 then integrates the measured current across the time period of the second pulse to calculate the capacity discharged during the second pulse. For example, if the current is 5 A for the 10 second pulse, the integrated current (i.e. the capacity discharged) is calculated as 50 mAh.

At step 412, the battery measurement module 152 controls the voltage sensor to measure the battery voltage near to the end of the second pulse (V_{end_second_pulse}), but whilst the second pulse is still being applied. In an example, the measurement of V_{end_second_pulse} takes place less than 100 ms before the end of the second pulse.

At step 413, the battery measurement module 152 calculates a second internal resistance (R_{I_2}) of the battery 104; that is, the internal resistance of the battery 104 based upon the second pulse.

The second internal resistance can be calculated as:

$${R}_{I \_ 2} = \frac{{V}_{before\_second \_pulse} - {V}_{end\_second \_pulse}}{{I}_{second\_pulse}}$$

At step 414, the battery measurement module 152 controls the voltage sensor to measure the battery voltage at rest, or open circuit voltage, after the second pulse has been applied (V_{OCV_2}). In an example, V_{OCV_2} is measured 1 second after the second pulse ends. This voltage can be measured by applying a small, or negligible, ‘trickle’ current from the battery 104 to the electronics.

In an alternative, the value of V_{end_second_pulse} can be used as the value of (V_{OCV_2}); however, using a separate measurement for (V_{OCV_2}) after the rest period (e.g. 1 second) can improve the repeatability of results.

At step 415, the battery measurement module 152 calculates the average internal resistance of the battery R_{I_average}, based upon R_{I_1} and R_{I_2}, as:

$${R}_{I\_average} = \frac{{R}_{I \_ 1} + {R}_{I \_ 2}}{2}$$

At step 416, the battery measurement module 152 calculates a quasi-open circuit voltage change (ΔV_{OCV}) between the open circuit voltage measured after the first pulse (V_{OCV_1}) and the open circuit voltage measured after the second pulse (V_{OCV_2}), as:

$${Δ V}_{OCV} = {V}_{OCV \_ 1} - {V}_{OCV \_ 2}$$

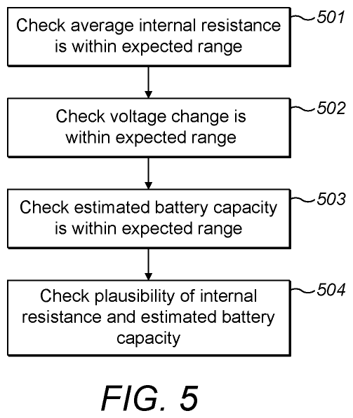

The values determined in the process described with reference to FIG. 4 are then utilised by the battery verification module 154 in the determination of whether parameter(s) of the battery 104 meet verification requirement(s) in order to set the aerosol generation device to an operable state when the parameter(s) meet the verification requirement(s), and to set the aerosol generation device to a restricted state when the parameter(s) do not meet the verification requirement(s). This is subsequently described with reference to FIG. 5.

Whilst two battery pulses are described with reference to FIG. 4, in some examples more than two battery pulses may be used. In such examples, improved reliability of the averaged internal resistance can be achieved.

The processing steps carried out in determining whether the parameter(s) of the battery 104 meet the verification requirement(s) are now described with reference to FIG. 5.

At step 501, the battery verification module 154 can perform an internal resistance verification requirement check. In this, the battery verification module 154 checks whether the average internal resistance (R_{I_average}) is within an expected range.

In more detail, the battery verification module 154 compares the measured average internal resistance to a predetermined range derived from the received battery verification parameters. The battery verification parameters can include a look-up table of predetermined internal resistance ranges for the type of battery inserted in the aerosol generation device (for example, as identified by the input at step 303 of FIG. 3) at a given ambient temperature and a given SoC. The battery verification module 154 uses the SoC determined at step 402 of FIG. 4, and optionally the ambient temperature measured during the first battery pulse, to look up the expected internal resistance range. As an alternative to the ambient temperature measured during the first battery pulse, the expected internal resistance range can instead be based on an ambient temperature measurement taken at any time during the process (for example the temperature check at step 401, or during the second pulse) as the battery temperature is not expected to change significantly during the process, and the temperature change impact in the operating temperature range (i.e. above the predetermined temperature threshold, for example equal to or above 15° C.) on the measured values should be relatively low.

The expected internal resistance can comprise an expected minimum internal resistance (R_{I_min}) and an expected maximum internal resistance (R_{I_max}) for the determined SoC and ambient temperature. The battery verification module 154 checks whether R_{I_average} falls within the expected internal resistance range by checking whether R_{I_average} is greater than or equal to R_{I_min}, and less than or equal to R_{I_max}.

When R_{I_average} is greater than or equal to R_{I_min}, and less than or equal to R_{I_max}, an internal resistance verification requirement of the battery 104 is met. However, when R_{I_average} is less than R_{I_min}, or greater than R_{I_max}, an internal resistance verification requirement of the battery 104 is not met.

When the internal resistance verification requirement of the battery 104 is not met, the controller 102 sets the aerosol generation device to the restricted, or locked, state and an aerosolisation session cannot be performed.

At step 502, the battery verification module 154 can perform a change in battery voltage verification requirement check. In this, the battery verification module 154 checks whether the voltage change (ΔV_{OCV}) of the battery 104 is within an expected range.

In more detail, the battery verification module 154 determines the drop in available capacity (or rise, in the case of a charging battery pulse) of the battery 104 during the second battery pulse using the integrated current during the second pulse (as described with reference to step 411 in FIG. 4) and an ideal available battery capacity of a new battery of the model determined at steps 303 and 304 described with reference to FIG. 3. This ideal battery voltage can be included in the battery verification parameters provided at step 305. The change in available capacity of the battery corresponds to a change in the SoC of the battery 104, and as such the battery verification module 154 determines the change in the SoC of the battery 104 during the second pulse using the integrated current and the ideal battery voltage.

In an example, the battery 104 has an ideal available battery capacity of 2000 mAh. If the integrated current in the second pulse is calculated as 50 mAh, the change in SoC is 2.5%.

At a high state of charge, the change in battery voltage corresponding to the determined change in the SoC defines an upper limit (ΔVₘₐₓ) to an expected voltage change range. At a low state of charge, the change in battery voltage corresponding to the determined change in the SoC defines a lower limit (ΔVₘᵢₙ) to an expected voltage change range. This is because the change in battery voltage is greater during a battery pulse for a battery with a higher SoC.

The received battery verification parameters can include a look-up table of upper limits and lower limits of the voltage change range for the battery model, for a given changes in SoC. The battery verification module 154 can then determine values for ΔVₘₐₓ and ΔVₘᵢₙ for the determined change in SoC.

The battery verification module 154 compares the value of ΔV_{OCV} (determined at step 416) to the values of ΔVₘₐₓ and ΔVₘᵢₙ. When ΔV_{OCV} is less than or equal to ΔVₘₐₓ and greater than or equal to ΔVₘᵢₙ, it is determined that the change in voltage verification requirement of the battery 104 is met. However, when ΔV_{OCV} is less than ΔVₘᵢₙ, or greater than ΔVₘₐₓ, the change in voltage verification requirement of the battery 104 is not met.

In the example above, the battery verification module 154 determines that the change in SoC is 2.5%. Using the look-up table, the battery verification module 154 can then determine that ΔVₘₐₓ=25 mV, and ΔVₘᵢₙ=17 mV. If the change in voltage (ΔV_{OCV}) is 27 mV, the change in voltage is outside of the expected range and the change in voltage verification requirement is not met.

When the change in voltage verification requirement of the battery 104 is not met, the controller 102 sets the aerosol generation device to the restricted, or locked, state and an aerosolisation session cannot be performed.

At step 503, the battery verification module 154 can perform an estimated battery capacity verification requirement check. In this, the battery verification module 154 estimates the capacity of the battery 104, and checks whether this capacity falls within an expected capacity range.

In more detail, the battery verification module 154 estimates the capacity of the battery 104 by using a determined value of the change in SoC (ΔSoC) as a percentage, based upon the value of ΔV_{OCV}, and the integrated current of the second pulse:

$$Estimated Capacity ( mAh ) = \frac{100}{Δ SOC} \times \int Idt$$

wherein ∫I dt is the integrated current in the second pulse.

In an example, ΔV_{OCV} can be converted to ΔSoC using a look-up table of ΔV_{OCV} values with corresponding percentage ΔSoC values for given SoC ranges. This can also be brought about using a matrix with ΔV_{OCV} per percentage change in SoC for a plurality of SoC ranges.

In the example described, where ΔV_{OCV} is 27 mV, the ΔSoC value is 2.7% (10 mV per 1% SoC) and the integrated current is 50 mAh, the battery verification module 154 determines the estimated capacity as 1852 mAh. As previously described for this example, for a high state of charge, the value of ΔV_{OCV} would be expected to be 25 mV, meaning that for an integrated current of 50 mAh, the estimated capacity of the battery would be 2000 mAh (i.e. the ideal available battery capacity of the new battery 104).

Upper and lower limits of the battery capacity can be included in the received battery verification parameters, defining an expected range of battery capacities. For example, for a 2000 mAh battery, a lower limit can be 1800 mAh, and an upper limit can be 2200 mAh. This accounts for manufacturing differences between batteries of the same model.

The estimated capacity of the battery falls within the expected battery capacity range when the estimated capacity of the battery 104 is greater than or equal to the lower battery capacity limit, and less than or equal to the upper battery capacity limit. The estimated capacity of the battery 104 falls outside of the expected battery capacity range when the estimated capacity of the battery is less than the lower battery capacity limit, or greater than the upper battery capacity limit.

When the estimated capacity of the battery 104 falls within the expected battery capacity range, an estimated battery capacity verification requirement is met. When the estimated capacity of the battery 104 falls outside the expected battery capacity range, an estimated battery capacity verification requirement is not met.

When the estimated battery capacity verification requirement is not met, the controller 102 sets the aerosol generation device to the restricted, or locked, state and an aerosolisation session cannot be performed.

In the aforementioned example, the estimated battery capacity is 1852 mAh, the lower limit is 1800 mAh, and the upper limit is 2200 mAh. In this example, the estimated battery capacity falls within the expected battery capacity range and the estimated battery capacity verification requirement is met.

At step 504, the battery verification module 154 can perform a plausibility verification requirement check. This plausibility check is based upon the estimated capacity of the battery 104 and the internal resistance (R_{I_average}). For lower capacities, the internal resistance of a battery 104 would be expected to be higher, and for higher capacities the internal resistance would be expected to be lower.

The battery verification module 154 can determine an expected range of battery capacity for a given internal resistance. For example, the received battery verification parameters can include a look-up table of expected ranges of capacity as a function of internal resistance for the model of battery 104 inserted into the aerosol generation device. When the estimated capacity falls within the expected range for the measured internal resistance of the battery 104, the plausibility check verification requirement is met. However, when the estimated capacity falls outside of the expected range for the measured internal resistance of the battery 104, the plausibility check verification requirement is not met. When the plausibility verification requirement is not met, the controller 102 sets the aerosol generation device to the restricted, or locked, state and an aerosolisation session cannot be performed.

As explained, the battery verification module 154 determines whether parameter(s) of the battery 104 meet verification requirement(s) in order for the controller 102 to set the aerosol generation device to an operable state when the parameter(s) meet the verification requirement(s), and to set the aerosol generation device to a restricted state when the parameter(s) do not meet the verification requirement(s). In the example of step 501, the parameter of the battery 104 is the determined internal resistance (R_{I_average}), and the verification requirement is that the determined internal resistance falls within the expected internal resistance range. In the example of step 502, the parameter of the battery 104 is the determined change in voltage (ΔV_{OCV}) of the battery 104, and the verification requirement is that the determined change in voltage of the battery 104 falls within the expected voltage change range. In the example of step 503, the parameter of the battery 104 is the estimated battery capacity, and the verification requirement is the expected capacity range. In the example of step 504, the parameter of the battery 104 is the estimated battery capacity, and the verification requirement is the expected capacity range for the determined internal resistance.

The battery verification process can comprise one or more of the checks described with reference to steps 501, 502, 503, and 504. That is, the battery verification requirement can comprise one or more of the internal resistance verification requirement (501), the change in voltage verification requirement (502), the estimated battery capacity verification requirement (503), and the plausibility verification requirement (504). All four checks can be used to minimise the expected number of false positives (i.e. a determination that the battery is verified in the case that it should not be) thereby lowering the risk. However, the process can be simplified by not using all four of these checks, thereby reducing computational complexity. Whether to implement all or some of the checks can depend on the battery model (for example, a battery with more capacity has more risk, and therefore can benefit from more checks) and/or the type of aerosol generation device in which the battery is used (for example, the number of checks used can be higher as for a device in which the battery is close to the consumer mouth during usage).

The skilled person will readily understand that when implementing the one or more steps 501, 502, 503 and 504, the one or more implemented steps can be carried out in any suitable order, and are no restricted to the order described with reference to FIG. 5.

When the verification requirements of each of the implemented battery verification checks are met, the controller 102 controls the aerosol generation device to be in an operable, or unlocked, state in which an aerosolisation session can be performed.

When at least one of the implemented battery verification requirements are not met, the controller 102 sets the aerosol generation device to the restricted, or locked, state and an aerosolisation session cannot be performed. This prompting can be indicated to the operator by way of an indicator in the aerosol generation device, for example a visual indicator (such as a light source, or display screen), an audible indicator (such as a speaker emitting a noise), or a haptic indicator (for example, vibrating in a predetermined manner).

In some examples, when at least one of the implemented battery verification checks are not met, the operator of the device can be prompted to repeat the battery verification process described with reference to FIGS. 3, 4 and 5.

When the verification requirements of each of the implemented battery verification checks are met in the repeated battery verification process, the controller 102 controls the aerosol generation device to be in an operable state in which an aerosolisation session can be performed. However, when at least one of the verification requirements are not met in the repeated battery verification process, the controller 102 sets the aerosol generation device to the restricted, or locked, state and an aerosolisation session cannot be performed. In this case, the device stays locked until the process is repeated, and is successful, with a new battery.

When the aerosol generation device is set to the restricted state, this can be indicated to the operator by way of an indicator in the aerosol generation device, for example a visual indicator (such as a light source, or display screen), an audible indicator (such as a speaker emitting a noise), or a haptic indicator (for example, vibrating in a predetermined manner).

The measured internal resistance of a battery 104 not being within the expected range (as described with reference to step 501), the measured voltage change of the battery 104 not being within the expected range (as described with reference to step 502), the estimated capacity not being within the expected range (step 503), and/or the estimated battery capacity not being within the expected range for the determined internal resistance (step 504), can be indicative of the battery 104 that has been inserted into the aerosol generation device not being the correct model, or being an aged, abused or second hand battery. Using such a battery can adversely affect the safety, reliability and/or quality of the operation of the aerosol generation device. As such, the controller 102 locks the device when at least one of these checks is not met in order to inhibit the use of the device with such an incorrect or deficient battery.

In the preceding description, the controller 102 (and battery measurement module 152 and battery verification module 154) can store instructions for controlling the aerosol generation device and power system in the described manners. The skilled person will readily understand that the controller 102 (and battery measurement module 152 and battery verification module 154) can be configured to execute any of the aforementioned manners in combination with one another as appropriate.

The processing steps described herein carried out by the controller 102 (and battery measurement module 152 and battery verification module 154) may be stored in a non-transitory computer-readable medium, or storage, associated with the controller 102 (and battery measurement module 152 and battery verification module 154). A computer-readable medium can include non-volatile media and volatile media. Volatile media can include semiconductor memories and dynamic memories, amongst others. Non-volatile media can include optical disks and magnetic disks, amongst others.

It will be readily understood to the skilled person that the preceding embodiments in the foregoing description are not limiting, features of each embodiment may be incorporated into the other embodiments as appropriate. It will also be understood that the steps of the processes described with reference to FIGS. 3, 4 and 5 need not be carried out in the order described, but can instead be carried out in any suitable order.

1. An aerosol generation device battery verification system, the system comprising:
a battery measurement module configured to perform a plurality of battery voltage measurements of a battery connected to an aerosol generation device;
a battery verification module configured to determine whether a parameter of the battery meets a verification requirement based upon the plurality of battery voltage measurements; and
a controller configured to set the aerosol generation device to an operable state when the parameter meets the verification requirement, and further configured to set the aerosol generation device to a restricted state when the parameter does not meet the verification requirement.

2. The aerosol generation device battery verification system of claim 1, wherein the aerosol generation device battery verification system is configured to apply a first battery pulse and a second battery pulse at a predetermined time interval after the first battery pulse, and the battery measurement module is configured to measure the plurality of battery voltage measurements based upon the first battery pulse and the second battery pulse.

3. The aerosol generation device battery verification system of claim 2, wherein the aerosol generation device battery verification system is configured to apply the first battery pulse and the second battery pulse as discharging battery pulses in which power flows from the battery to a heater of the aerosol generation device; and/or
wherein the aerosol generation device battery verification system is configured to apply the first battery pulse and the second battery pulse as charging battery pulses in which power flows to the battery from a second power source.

4. The aerosol generation device battery verification system of claim 3, wherein the aerosol generation device battery verification system is configured to apply the first battery pulse and the second battery pulse as discharging battery pulses when a state of charge of the battery is greater than a predetermined state of charge threshold.

5. The aerosol generation device battery verification system of claim 3, wherein the aerosol generation device battery verification system is configured to apply the first battery pulse and the second battery pulse as charging battery pulses when a state of charge of the battery is not greater than a predetermined state of charge threshold.

6. The aerosol generation device battery verification system of claim 3, wherein the second power source comprises one or more supercapacitors in the aerosol generation device; or
wherein the second power source comprises an external power source to which the aerosol generation device is connected.

7. The aerosol generation device battery verification system of claim 2, wherein determining whether the parameter of the battery meets the verification requirement comprises:
calculating an internal resistance of the battery based upon the plurality of battery voltage measurements, and determining that the parameter of the battery meets the verification requirement when the calculated internal resistance is within a predetermined internal resistance range.

8. The aerosol generation device battery verification system of claim 7, wherein the plurality of battery voltage measurements comprise battery voltage measurements measured before the first battery pulse, during the first battery pulse, between the first battery pulse and the second battery pulse, and during the second battery pulse; and
the battery verification module is configured to calculate the internal resistance of the battery based upon the battery voltage measurements before the first battery pulse, during the first battery pulse, between the first battery pulse and the second battery pulse, and during the second battery pulse.

9. The aerosol generation device battery verification system of claim 7, wherein the predetermined internal resistance range is based upon a state of charge of the battery.

10. The aerosol generation device battery verification system of claim 9, wherein the predetermined internal resistance range is based upon a state of charge of the battery and an ambient temperature proximal to the aerosol generation device.

11. The aerosol generation device battery verification system of claim 2, wherein determining whether the parameter of the battery meets the verification requirement comprises:
calculating a change in voltage of the battery based upon the plurality of battery voltage measurements, and determining that the parameter of the battery meets the verification requirement when the change in voltage of the battery falls within a predetermined voltage change range.

12. The aerosol generation device battery verification system of claim 11, wherein the plurality of battery voltage measurements comprise a first open circuit battery voltage measured between the first battery pulse and a second open circuit battery voltage measured after the second battery pulse; and
the change in voltage of the battery is determined as a difference between the first open circuit battery voltage and the second open circuit battery voltage.

13. The aerosol generation device battery verification system of claim 2, wherein determining whether the parameter of the battery meets the verification requirement comprises:
calculating an available capacity of the battery based upon the plurality of battery voltage measurements, and determining that the parameter of the battery meets the verification requirement when the calculated available capacity of the battery is within a predetermined capacity range.

14. The aerosol generation device battery verification system of claim 13, wherein the plurality of battery voltage measurements comprise a first open circuit battery voltage measured between the first battery pulse and the second battery pulse, and a second open circuit battery voltage measured after the second battery pulse; and
the battery verification module is configured to calculate the available capacity of the battery based upon the first open circuit battery voltage, the second open circuit battery voltage, and an integrated current during the second battery pulse.

15. The aerosol generation device battery verification system of claim 2, wherein determining whether the parameter of the battery meets the verification requirement comprises:
calculating an available capacity of the battery and an internal resistance of the battery based upon the plurality of battery voltage measurements, and determining that the parameter of the battery meets the verification requirement when the calculated available capacity of the battery is within a predetermined capacity range for the calculated internal resistance of the battery.

16. The aerosol generation device battery verification system of claim 15, wherein the battery verification module is configured to:
calculate the available capacity of the battery based upon a first open circuit battery voltage measured between the first battery pulse and the second battery pulse, a second open circuit battery voltage measured after the second battery pulse, and an integrated current during the second battery pulse; and
calculate the internal resistance of the battery based upon battery voltage measurements before the first battery pulse, during the first battery pulse, between the first battery pulse and the second battery pulse, and during the second battery pulse;
wherein the predetermined capacity range based upon a relationship between internal resistance and capacity range of the battery.

17. The aerosol generation device battery verification system of claim 1, wherein the operable state comprises an unlocked state in which an aerosolisation session can be performed, and the restricted state comprises a locked state in which an aerosolisation session cannot be performed.

18. The aerosol generation device of claim 1, wherein the aerosol generation device battery verification system further comprises a temperature sensor module configured to determine an ambient temperature proximal to the aerosol generation device, and the battery measurement module is configured to perform the plurality of battery voltage measurements when the determined ambient temperature is greater than a predetermined temperature threshold, and configured to not perform the plurality of battery voltage measurements when the determined ambient temperature is not greater than a predetermined temperature threshold.

19. The aerosol generation device battery verification system of claim 1, wherein the system is configured to be communicatively coupled to an external device;
the external device is configured to receive an input indicating a type of battery connected to the aerosol generation device, and determine the verification requirement for the battery; and
the aerosol generation device battery verification system is configured to receive the verification requirement from the external device.

20. The aerosol generation device battery verification system of claim 1, wherein the battery measurement module is configured to perform a plurality of battery voltage measurements in response to a battery being connected to the aerosol generation device.

21. An aerosol generation device comprising the aerosol generation device battery verification system of claim 1.

22. An aerosol generation device battery verification method, the method comprising:
performing a plurality of battery voltage measurements of a battery connected to an aerosol generation device;
determining whether a parameter of the battery meets a verification requirement based upon the plurality of battery voltage measurements; and
setting the aerosol generation device to a operable state when the parameter meets the verification requirement, and setting the aerosol generation device to a restricted state when the parameter does not meet the verification requirement.

23. A non-transitory computer-readable medium storing instructions that when executed by one or more processors of an aerosol generation device battery verification system cause the one or more processors to perform steps comprising:
performing a plurality of battery voltage measurements of a battery connected to an aerosol generation device;
determining whether a parameter of the battery meets a verification requirement based upon the plurality of battery voltage measurements; and
setting the aerosol generation device to a operable state when the parameter meets the verification requirement, and setting the aerosol generation device to a restricted state when the parameter does not meet the verification requirement.
